(19) United States
(12) Patent Application Publication
(10) Pub. No.: US 2025/0259920 A1
(43) Pub. Date: Aug. 14, 2025

(54) SEMICONDUCTOR DEVICES AND METHODS OF MANUFACTURING SEMICONDUCTOR DEVICES

(71) Applicant: Amkor Technology Singapore Holding Pte. Ltd., Singapore (SG)

(72) Inventors: Kyun Ahn, Gyeonggi-do (KR); Gam Han Yong, Incheon (KR); Eun Young Lee, Lee (KR)

(21) Appl. No.: 18/439,963

(22) Filed: Feb. 13, 2024

(51) Int. Cl. H01L 23/498; H01L 23/00; H01L 23/31; H01L 23/48; H01L 23/522; H01L 23/538; H01L 25/00; H01L 25/065

(52) U.S. Cl. CPC H01L 23/49822; H01L 23/31; H01L 23/481; H01L 23/5226; H01L 23/5385; H01L 24/16; H01L 24/32; H01L 24/73; H01L 25/0652; H01L 25/50; H01L 2224/16225; H01L 2224/32225; H01L 2224/73204; H01L 2924/181; H01L 2924/19041

(57) ABSTRACT

In one example, an electronic device includes a lower redistribution structure, an upper redistribution structure, a first electronic component coupled to the upper redistribution structure, a second electronic component coupled to the upper redistribution structure, and a routing component. The routing component includes a routing redistribution structure, a component die, component through-interconnects, and a component encapsulant. The routing redistribution structure is on the component encapsulant and coupled to the upper redistribution structure. The component die includes a component die substrate and a die interface structure on the component die substrate. The die interface structure is coupled to the routing redistribution structure. The component through-interconnects extend through the component encapsulant and couple the routing redistribution structure to the lower redistribution structure. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2J show an example method for manufacturing an example component die of the electronic device of FIG. 1.

FIGS. 3A to 3F show an example method for manufacturing an example routing component of the electronic device of FIG. 1.

FIGS. 4A to 4H show an example method for manufacturing the example electronic device of FIG. 1.

FIG. 5 shows a cross-sectional view of another example electronic device.

FIG. 6 shows a cross-sectional view of yet another example electronic device.

### DESCRIPTION

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” “third,” etc. may be used herein to describe various elements. These terms are only used to distinguish one element from another. The elements described using “first,” “second,” etc. should not be limited by these terms. For example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical coupling or a mechanical coupling.

In various embodiments, an electronic device can include a lower redistribution structure, an upper redistribution structure, a first electronic component coupled to the upper redistribution structure, a second electronic component coupled to the upper redistribution structure, and a routing component. The routing component can include a routing redistribution structure, a component die, component through-interconnects, and a component encapsulant. The routing redistribution structure can be on the component encapsulant and coupled to the upper redistribution structure. The component die can include a component die substrate and a die interface structure on the component die substrate. The die interface structure can be coupled to the routing redistribution structure. The component through-interconnects can extend through the component encapsulant and couple the routing redistribution structure to the lower redistribution structure.

In some embodiments, an electronic device can include a lower redistribution structure, an upper redistribution structure, a first electronic component coupled to the upper redistribution structure, a second electronic component coupled to the upper redistribution structure, and a component die coupled to the lower redistribution structure and the upper redistribution structure lower side. The component die can include a component die substrate, one or more passive elements along an upper surface of the component die substrate, a die interface structure over the component die substrate and the one or more passive elements, and die through-interconnects. The die through-interconnects can pass through the component die substrate and couple the one or more passive elements to the lower redistribution structure.

In further embodiments, a method of manufacturing an electronic device can include providing a lower redistribution structure, providing an upper redistribution structure, providing a routing component on the lower redistribution structure. The method can also include providing a first electronic component coupled to the upper redistribution structure and providing a second electronic component coupled to the upper redistribution structure.

Other examples are included in the present disclosure. Such examples may be found in the figures, in the claims, or in the description of the present disclosure.

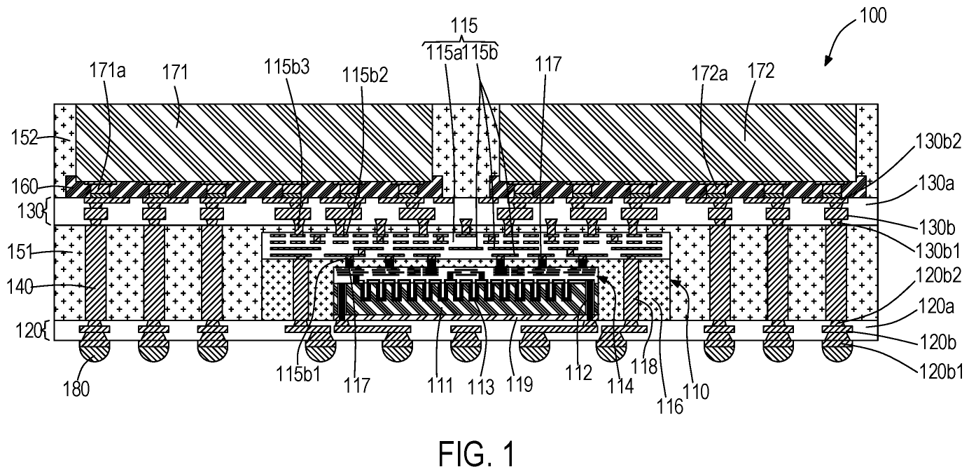

FIG. 1 shows a cross-sectional view of an example electronic device 100. In the example shown in FIG. 1, electronic device 100 can comprise routing component 110, lower (or first) redistribution structure 120, upper (or second) redistribution structure 130, device through-interconnects 140, lower (or first) encapsulant 151, upper (or second) encapsulant 152, underfill 160, electronic component 171, electronic component 172, and external interconnects 180.

Routing component 110 can comprise component die 111, routing redistribution structure 115, component encapsulant 116, and component through-interconnects 118. Component die 111 can comprise die through-interconnects 112, passive element 113, and die interface structure 114. Routing redistribution structure 115 can comprise dielectric structure 115a and conductive structure 115b. Conductive structure 115b can comprise lower (or first) side terminals 115b1, upper (or second) side terminals 115b2, and one or more conductive layers coupling respective ones of lower side terminals 115b1 to respective ones of upper side terminals 115b2.

Lower redistribution structure 120 can comprise dielectric structure 120a and conductive structure 120b. Conductive structure 120b can comprise lower (or first) side terminals 120b1 and upper (or second) side terminals 120b2, and one or more conductive layers coupling respective ones of lower side terminals 120b1 to respective ones of uppers die terminals 102b2. Upper redistribution structure 130 can comprise dielectric structure 130a and conductive structure 130b. Conductive structure 130b can comprise lower (or first) side terminals 130b1, upper (or second) side terminals 130b2, and one or more conductive layers coupling respective ones of the lower side terminals 130b1 to respective ones of the upper side terminals 130b2. Component interconnects 171a can couple electronic component 171 to upper redistribution structure 130 via upper side terminals 130b2. Component interconnects 172a can couple electronic component 172 to upper redistribution structure 130 via upper side terminals 130b2.

Routing component 110, lower redistribution structure 120, upper redistribution structure 130, device through-interconnects 140, lower encapsulant 151, upper encapsulant 152, underfill 160, and external interconnects 180 can be referred to as an electronic package, such as a semiconductor package. The electronic package can protect electronic components 171 and 172 from external elements or environmental exposure and/or can provide electrical connection between electronic component 171 and electronic component 172 and/or between external devices/packages and electronic components 171 and 172.

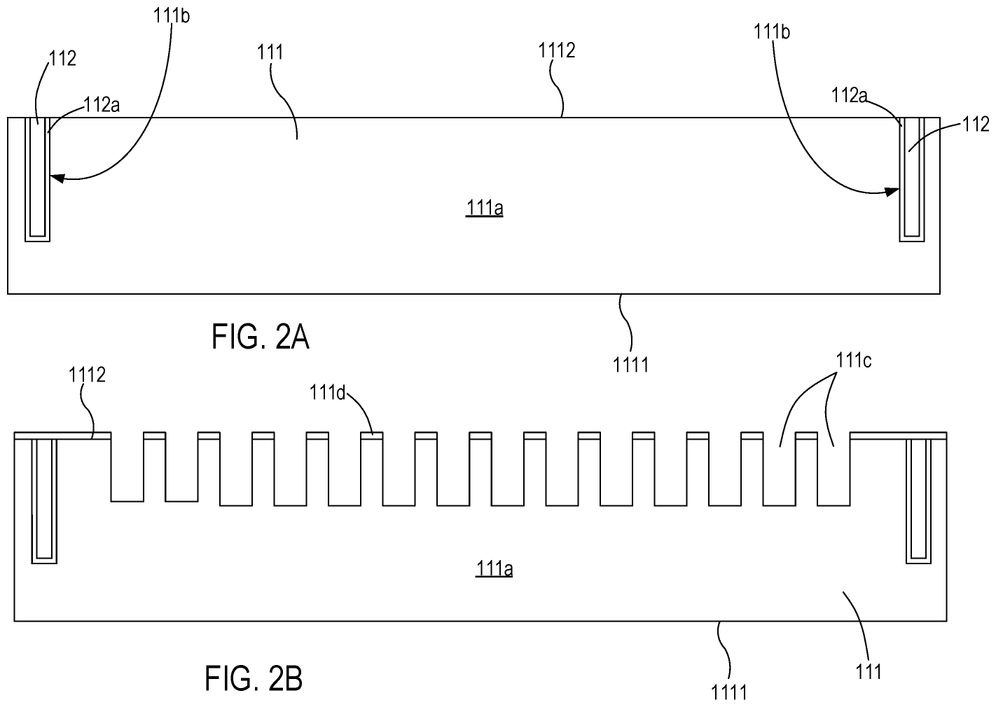

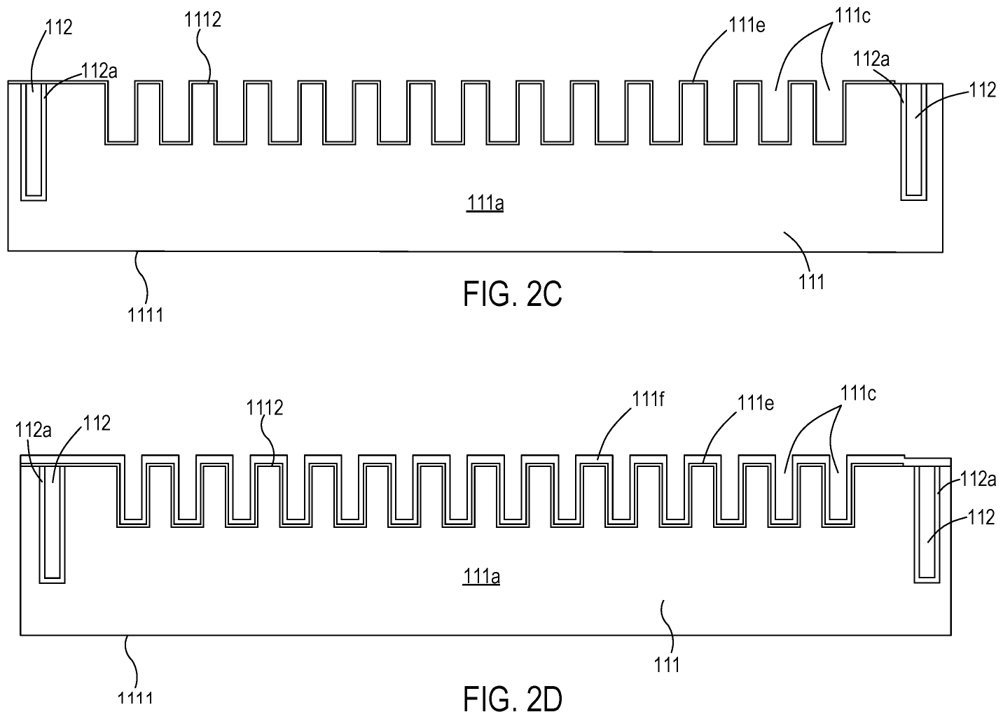

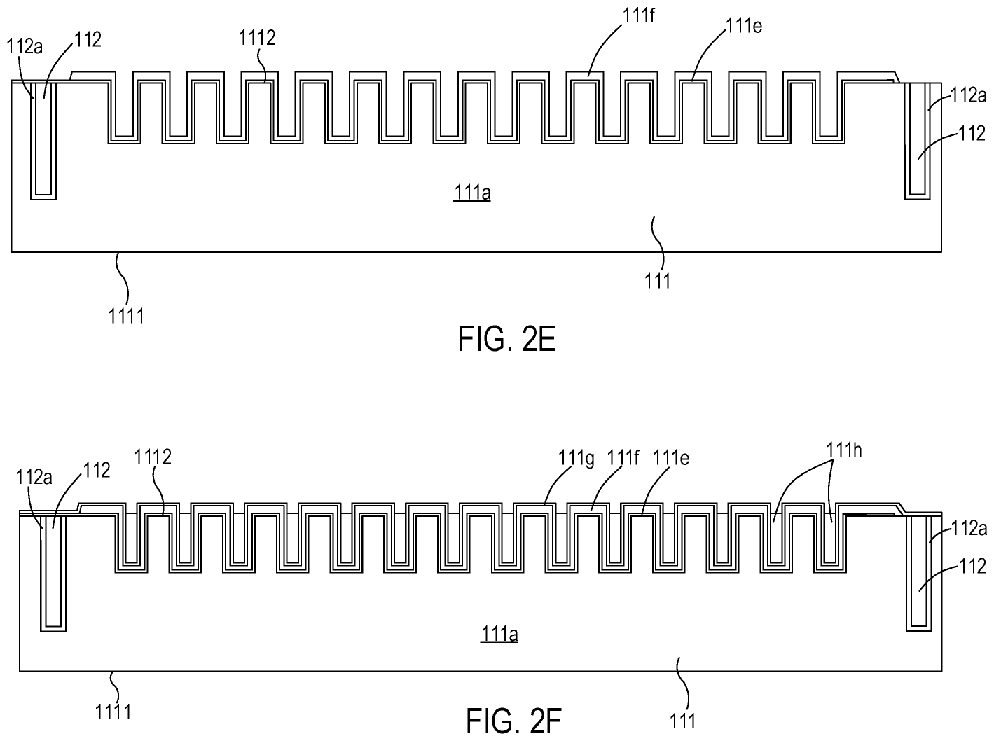

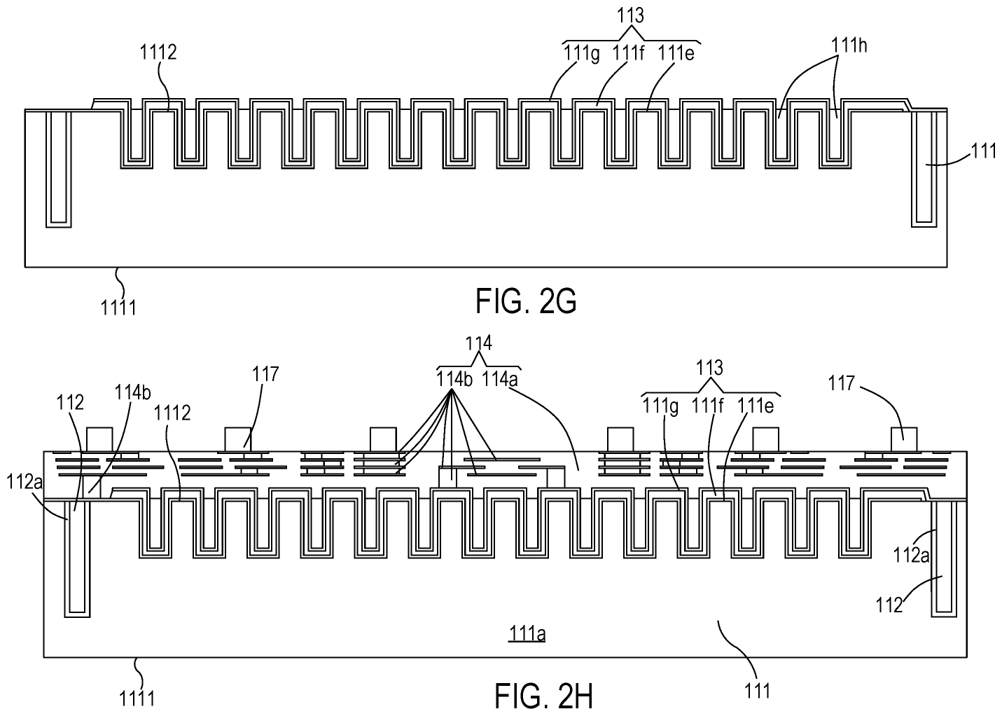

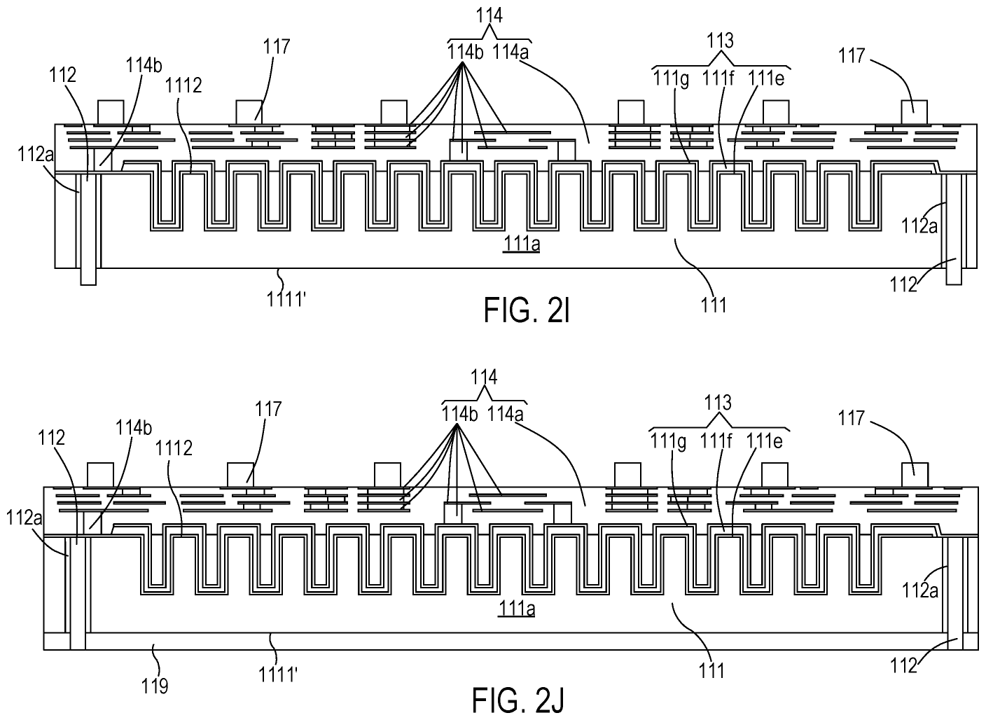

FIGS. 2A to 2J show an example method for manufacturing component die 111. While FIGS. 2A to 2J show a single component die 111, it is contemplated and understood that the illustrated component die 111 can be included on a wafer comprising a plurality of die that are similar, or identical, to component die 111. The wafer can be sawed in a singulation step, as described below with reference to FIG. 2J, to provide individual component die 111.

FIG. 2A shows a cross-sectional view of component die 111 at an early stage of manufacture. In accordance with various examples, component die 111 can be provided as part of a wafer comprising a plurality of component die 111. Component die 111 can comprise a lower (or first) side 1111 and an upper (or second) side 1112 opposite lower side 1111. Component die 111 can comprises a component die substrate 111a. In some examples, material of the component die substrate 111a can be semiconductor material (e.g., silicon (Si), silicon carbide (SiC)). In some examples, component die substrate 111a can comprise a pure silicon substrate, an n-type silicon substrate, or a p-type silicon substrate. In some examples, material of the component die substrate 111a can be glass, ceramic, or epoxy molding compound. The thickness of component die 111 can range from approximately 50 micrometers (μm) to approximately 780 μm. In some examples, component die 111 can include active elements or passive elements formed during the front-end manufacturing of component die 111. In some examples, component die 111 can be devoid of any active elements or passive elements.

In some examples, vias 111b can be provided in upper side 1112 of component die 111. Vias 111b can be located proximate the lateral sides of component die 111 (e.g., proximate saw streets located between adjacent component die 111). For example, vias 111b can be located closer to the lateral side of component die 111 as compared to passive element(s) 113, as described in further detail below. In some examples, vias 111b can be provided by etching, laser drilling, or any other suitable method. Vias 111b extend partially through component die 111, such that a portion of component die substrate 111a remains between the floor of each via 111b and lower side 1111 of component die 111. In some examples, the depth of vias 111b can range from approximately 60 μm to approximately 100 μm.

In accordance with various examples, die through-interconnects 112 can be provided in vias 111b. Die through-interconnects 112 can comprise aluminum, copper, gold, silver, nickel, titanium, tungsten, tantalum, or palladium, and can be provided by electroless plating, electrolytic plating, sputtering, or any other suitable metal deposition technique. The height of die through-interconnects 112 can range from approximately 60 μm to approximately 100 μm. In some examples, a dielectric or insulating material 112a can be first provided in vias 111b, such that insulating material 112a is located between the conductive material of die through-interconnects 112 and the material of component die substrate 111a. The thickness of insulating material 112a can range from approximately 0.25 μm to approximately 1 μm. Die through-interconnects 112 can contact insulating material 112a. Die through-interconnects 112 can be electrically insulated from material of the component die substrate 111a by insulating material 112a.

FIG. 2B shows a cross-sectional view of component die 111 at a later stage of manufacture. In accordance with various examples, trenches 111c can be provided in upper side 1112 of component die 111. In some examples, trenches 111c can be provide in the component die 111 by removing a portion of component die 111 exposed through openings in a patterned mask 111d located on upper side 1112 of component die 111. In some examples, mask 111d can be provided on upper side 1112 of component die 111 using a deposition process such as plasma enhanced chemical vapor deposition (PECVD). Mask 111d can be patterned using, for example, a photolithography process and an etching process. The patterning process can provide openings in mask 111d through which a portion of component die 111 can be removed using an etching process such as deep reactive ion etching (DRIE) to form trenches 111c.

The depth of trenches 111c can range from approximately 10 μm to approximately 50 μm. After providing trenches 111c, mask 111d can be removed by, for example, wet etching. In some examples, residue in trenches 111c can be removed by oxygen plasma. In some examples, trenches 111c can increase the capacitance of component die 111 by increasing the surface area of the component die substrate 111a.

FIG. 2C shows a cross-sectional view of component die 111 at a later stage of manufacture. In the example shown in FIG. 2C, lower conductive layer 111 can be provided in trenches 111c and on upper side 1112 of component die 111. In some examples, lower conductive layer 111 can comprise doped semiconductor material (e.g., n-type silicon, p-type silicon, etc.). For example, lower conductive layer 111 can be formed by depositing a doped semiconductor material (e.g., doped polysilicon) along the sidewalls and floor of trenches 111c and along upper side 1112. The dopants can be a p-type dopant or an n-type dopant. The doped semiconductor material can be deposited by chemical vapor deposition such as, for examples, low pressure chemical vapor deposition (LPCVD). In some examples, lower conductive layer 111 can comprise a metal such as aluminum, copper, gold, silver, nickel, titanium, tungsten, tantalum, or palladium, and can be deposited by electroless plating, electrolytic plating, sputtering, or any other suitable metal deposition technique. The thickness of lower conductive layer 111 can range from approximately 0.1 μm to approximately 1 μm. In some examples, lower conductive layer 111 can function as a lower electrode of a capacitor, as discussed in further detail below. In some examples, component die 111 itself can function as the capacitor lower electrode. For example, lower conductive layer 111 can be provided by doping the substrate material of component die 111 along trenches 111c and upper side 1112. In some examples, one or more of die through-interconnects 112 is exposed from or devoid of lower conductive layer 111. For example, in FIG. 2C, the die through-interconnects 112 toward the right lateral side of component die 111 is exposed from or devoid of lower conductive layer 111, and the die through-interconnects 112 toward the left lateral side of component die 111 is contacting lower conductive layer 111e.

FIG. 2D shows a cross-sectional view of component die 111 at a later stage of manufacture. In the example shown in FIG. 2D, dielectric layer 111f can be provided on lower conductive layer 111 and upper side 1112 of component die 111. In some examples, dielectric layer 111f can be referred to as a capacitor dielectric layer. In some examples, dielectric layer 111f can be, for example, SiO2, Si3N4, or an oxide-nitride-oxide (ONO). Dielectric layer 111f can be provided using a deposition process such as chemical vapor deposition (CVD). The thickness of dielectric layer 111f can range from approximately 0.01 μm to approximately 0.05 μm.

FIG. 2E shows a cross-sectional view of component die 111 at a later stage of manufacture. In the example shown in FIG. 2E, portions of dielectric layer 111f can be removed to expose lower conductive layer 111 and/or one or more die through-interconnects 112. For example, a portion of dielectric layer 111f can be removed from over the portion of lower conductive layer 111 that is located on die through-interconnect 112, thereby exposing the portion of lower conductive layer 111 located on die through-interconnect 112 from dielectric layer 111f. A portion of dielectric layer 111f can also be removed from over the die through-interconnects 112 that is exposed from lower conductive layer 111, thereby exposing the upper side of die through-interconnect 112 from dielectric layer 111f. The portion of dielectric layer 111f can be removed by etching or any other suitable removal technique.

FIG. 2F, shows a cross-sectional view of component die 111 at a later stage of manufacture. In the example shown in FIG. 2F, upper conductive layer 111g can be provided over dielectric layer 111f, lower conductive layer 111, die through-interconnect(s) 112, and upper side 1112 of component die 111. In some examples, upper conductive layer 111g can comprise doped semiconductor material (e.g., n-type silicon, p-type silicon, etc.). For example, upper conductive layer 111g can be formed by depositing a doped semiconductor material (e.g., doped polysilicon) along the upper sides of dielectric layer 111f, lower conductive layer 111, die through-interconnect(s) 112, and upper side 1112 of component die 111. The dopants can be a p-type dopant or an n-type dopant. The doped semiconductor material can be deposited by chemical vapor deposition such as, for examples, by LPCVD. In some examples, upper conductive layer 111g can comprise a metal such as aluminum, copper, gold, silver, nickel, titanium, tungsten, tantalum, or palladium, and can be deposited by electroless plating, electrolytic plating, sputtering, or any other suitable metal deposition technique. The thickness of upper conductive layer 111g can range from approximately 0.1 μm to approximately 1 μm.

In some examples, after providing upper conductive layer 111g, the remaining empty volume of trench 111c (FIG. 2D) can be filled, at least partially, with a dielectric 111h. Dielectric 111h can comprise an inorganic dielectric material (e.g., SiO2, Si3N4, etc.) or an organic dielectric material (e.g. polyimide (PI), polybenzoxazole (PBO), benzocyclobutene (BCB), Ajinomoto build-up film (ABF), etc.). While FIG. 2F shows dielectric 111h filling trench 111c, it is contemplated and understood that in some examples, after providing upper conductive layer 111g, the remaining empty volume of trench 111c (FIG. 2D) can remain devoid of material.

FIG. 2G, shows a cross-sectional view of component die 111 at a later stage of manufacture. In the example shown in FIG. 2G, portions of upper conductive layer 111g can be removed from over lower conductive layer 111 by etching or any other suitable removal process. For example, the portions of upper conductive layer 111g that are located on lower conductive layer 111 can be removed to expose lower conductive layer 111. After removal of the portions of upper conductive layer 111g located on lower conductive layer 111, the remaining portions of upper conductive layer 111g can be separated from lower conductive layer 111 by dielectric layer 111f.

In some examples, one or more first die through-interconnects 112 toward a first lateral side of component die 111 (e.g., toward the left lateral side in FIG. 2G) can be coupled to or contacting lower conductive layer 111, and one or more second die through-interconnects 112 toward a second lateral side of component die 111 (e.g., toward the right lateral side in FIG. 2G) can be coupled to or contacting upper conductive layer 111g. In some examples, upper conductive layer 111g can provide an upper electrode of a capacitor. In some examples, lower conductive layer 111, dielectric layer 111f, and upper conductive layer 111g can be referred to as passive element 113. For example, lower conductive layer 111, dielectric layer 111f, and upper conductive layer 111g can provide one or more deep trench capacitor(s) (DTCs) in component die 111. In some examples, die through-interconnects 112 can be outside passive element(s) 113. For examples, die through-interconnects 112 can be located closer to the lateral sides of component die 111 as compared to passive element(s) 113.

FIG. 2H shows a cross-sectional view of component die 111 at a later stage of manufacture. In the example shown in FIG. 2H, die interface structure 114 can be provided over upper side 1112 of component die 111. In some examples, die interface structure 114 can be provided over passive element(s) 113 and die through-interconnects 112. Die interface structure 114 can comprise or be referred to as a die redistribution structure. Die interface structure 114 can comprise dielectric structure 114a and conductive structure 114b. Dielectric structure 114a can comprise one or more dielectric layers made of a dielectric material interleaved between layers of conductive structure 114b. Dielectric structure 114a can comprise one or more dielectric layers of inorganic dielectric material such as SiO2, Si3N4, or ONO, or one or more layers of organic dielectric material such as polyimide (PI), benzocyclobutene (BCB), polybenzoxazole (PBO), resin, or Ajinomoto build-up film (ABF). The thickness of dielectric structure 114a can range from approximately 2 μm to approximately 50 μm. The thickness of dielectric structure 114a can refer to individual layers of dielectric structure 120a. Conductive structure 114b can comprise one or more conductive layers defining signal distribution elements (e.g., traces, vias, pads, conductive paths, or UBMs). Conductive structure 114b can comprise aluminum, copper, gold, silver, nickel, or palladium. Conductive structure 114b can distribute electrical signals in a vertical direction and a lateral direction through die interface structure 114. In some embodiments, conductive structure 114b can be coupled to passive elements 113 along the upper surface of the component die substrate 111a. The thickness of conductive structure 114b can range from approximately 1 μm to approximately 10 μm. The thickness of conductive structure 114b can refer to the individual conductive layers of conductive structure 114b.

In some examples, die interconnects 117 can be provided over die interface structure 114. Die interconnects 117 can comprise or be referred to as bumps, pads, lands, or pillars. Die interconnects 117 can comprise aluminum, copper, gold, silver, nickel, palladium, or solder. The thicknesses of die interconnects 117 can range from approximately 1 μm to approximately 50 μm.

FIG. 2I shows a cross-sectional view of component die 111 at a later stage of manufacture. In the example shown in FIG. 2I, grinding and/or etching processes can be performed to provide new lower side 1111′ of component die 111 and expose die through-interconnects 112. In some examples, after grinding, the lower side of component die 111 and lower side of die through-interconnects 112 can be coplanar. In some examples, after grinding, the lower side of component die 111 can be etched using a wet etching or dry etching process. In some examples, after etching the lower side of die through-interconnects 112 can protrude from lower side 1111′ of component die 111. The length of the protruding portion of die through-interconnect 112 can range from approximately 0 μm to approximately 15 μm.

FIG. 2J shows a cross-sectional view of component die 111 at a later stage of manufacture. In the example shown in FIG. 2J, die attach film (or adhesive) 119 can be provided on lower side 1111′ of component die 111. In some examples, die attach film 119 can cover the lower side of die through-interconnects 112. In some examples, the lower side of die through-interconnects 112 can be exposed through the die attach film 119. The thicknesses of die attach film 119 can range from approximately 5 μm to approximately 20 μm. Die attach film 119 can serve to attach component die 111 on carrier 191 or lower redistribution structure 120, as described in further detail below.

In some examples, through the above-described processes, component dies 111 can be provided in a wafer form, and individual independent component dies 111 can be provided by sawing or singulation in a final stage. Through this sawing process, the lateral side of component die 111, the lateral side of die interface structure 114, and the lateral side of die attach film 119 can be coplanar.

While component die 111 is illustrated having a deep trench capacitor (e.g., passive element 113), it is contemplated and understood that in some examples component die 111 can be formed without the deep trench capacitor. For example, component die 111 can include die interface structure 114 without the deep trench capacitor or any other passive or active components.

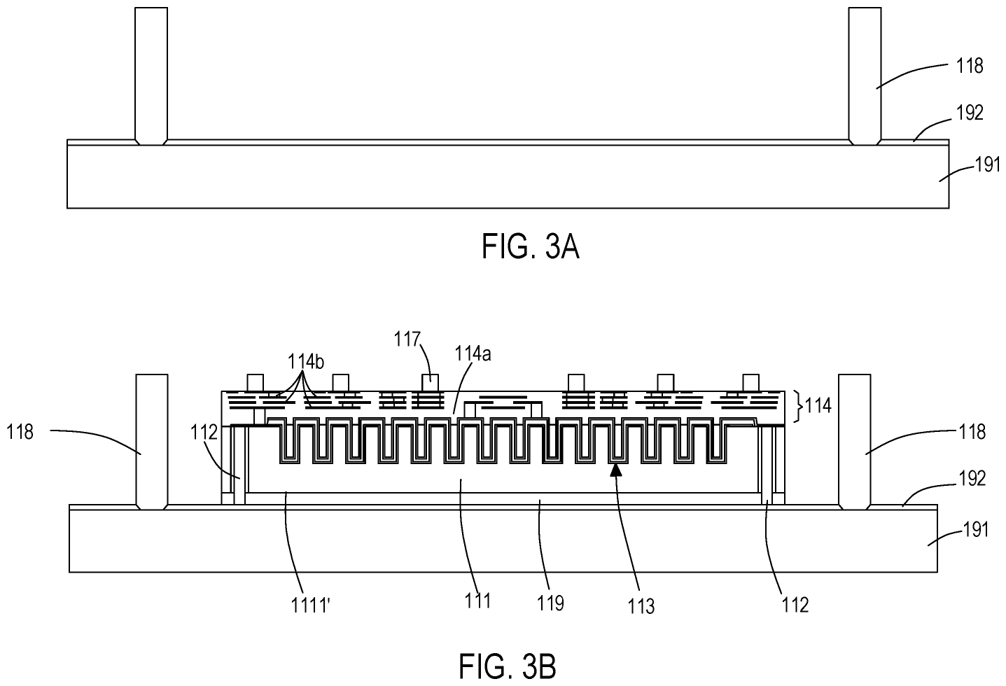

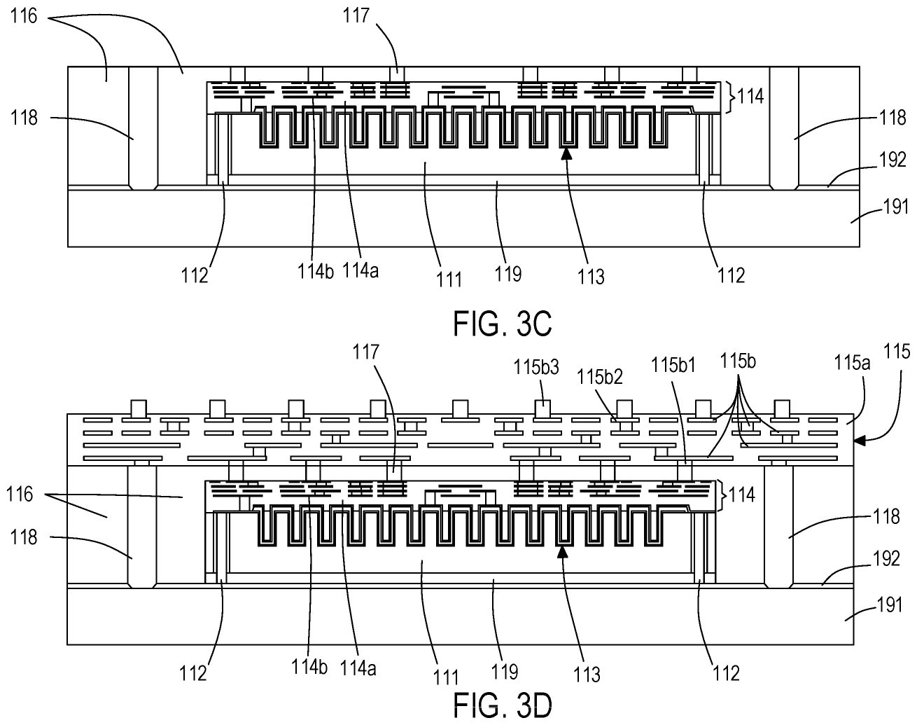

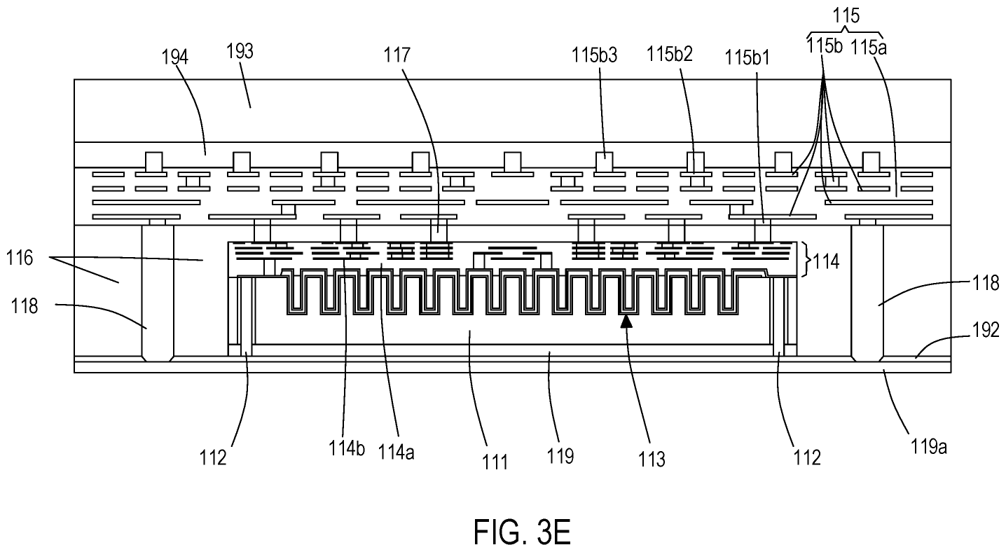

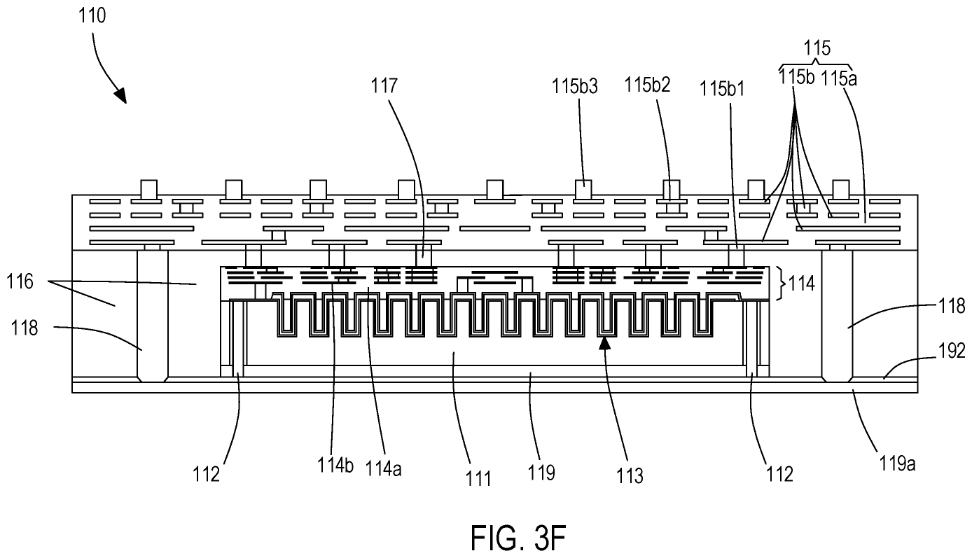

FIGS. 3A to 3F show cross-sectional views of an example method for manufacturing an example routing component 110. Although one routing component 110 is shown in FIGS. 3A to 3F, it is contemplated and understood that a plurality of routing components 110 can be simultaneously (or nearly simultaneously) formed in a wafer or panel form. The wafer or panel having multiple routing components 110 can be sawed in a singulation step, as described below with reference to FIG. 3F, to provide individual routing components 110.

FIG. 3A shows a cross-sectional view of routing component 110 at an early stage of manufacture. In the example shown in FIG. 3A, component through-interconnects 118 can be provided on carrier 191. In some examples, carrier 191 can be provided in the form of a circular wafer or a rectangular panel. In some examples, carrier 191 can comprise silicon, glass, ceramic, or metal. In some examples, dielectric layer 192 can be provided on carrier 191, and then patterned. By the patterning, a partial region of carrier 191 can be exposed. Component through-interconnects 118 can be provided on portions of carrier 191 exposed through dielectric layer 192. Each of component through-interconnects 118 can comprise a lower side in contact with carrier 191, an upper side opposite the lower side, and lateral sides between the lower side and the upper side. Component through-interconnects 118 can comprise or be referred to as pillars, posts, through mold vias (TMVs), copper core solder balls (CCBs), solder balls, or wires. In some examples, component through-interconnects 118 can be provided by electroless plating, electrolytic plating, sputtering, reflow, or wire bonding. In some examples, component through-interconnects 118 can comprise aluminum, copper, gold, silver, nickel, palladium, or solder. The thickness (or height) of component through-interconnect 118 can range from approximately 150 μm to approximately 300 μm. The width of component through-interconnect 118 can range from approximately 50 μm to approximately 150 μm.

FIG. 3B shows a cross-sectional view of routing component 110 at a later stage of manufacture. In the example shown in FIG. 3B, component die 111 can be located on carrier 191. In some examples, die attach film 119 on lower side 1111′ of component die 111 can be adhered to dielectric layer 192 on carrier 191. In some examples, component die 111 can be provided between component through-interconnects 118. In some examples, component die 111 can be spaced apart laterally from component through-interconnects 118. Component through-interconnects 118 can be located adjacent one, two, three, or all four lateral sides of component die 111. In some examples, the upper sides of die interconnects 117 and the upper sides of component through-interconnects 118 can be coplanar.

FIG. 3C shows a cross-sectional view of routing component 110 at a later stage of manufacture. In the example shown in FIG. 3C, component encapsulant 116 can be provided over carrier 191, component die 111, and component through-interconnects 118. Component encapsulant 116 can surround or contact component die 111 and component through-interconnects 118. Component encapsulant 116 can cover the lateral sides and the upper side of component die 111. Component encapsulant 116 can cover the lateral sides and the upper sides of component through-interconnects 118. In some examples, component encapsulant 116 can surround or contact die interconnects 117. In some examples, component encapsulant 116 can comprise or be referred to as an epoxy molding compound, resin, filler-reinforced polymer, a B stage compression film, or gel. In some examples, component encapsulant 116 can comprise epoxy resin or phenolic resin, carbon black, and silica filler. In some examples, component encapsulant 116 can be provided by compression molding, transfer molding, liquid encapsulant molding, vacuum lamination, paste printing, or film assistant molding. The thickness of component encapsulant 116 can range from approximately 100 μm to approximately 300 μm. Component encapsulant 116 can protect component die 111 and component through-interconnects 118 from external elements or environment exposure.

In accordance with various examples, the upper sides of die interconnects 117 and the upper sides of component through-interconnects 118 can be exposed through the upper side of component encapsulant 116. In some examples, component encapsulant 116 can initially be provided covering the upper sides of die interconnects 117 or component through-interconnects 118. In such an example, the thickness of component encapsulant 116 can be reduced by grinding. After grinding, the upper side of component encapsulant 116, the upper side of die interconnects 117, and the upper side of component through-interconnects 118 can be coplanar.

FIG. 3D shows a cross-sectional view of routing component 110 at a later stage of manufacture. In the example shown in FIG. 3D, routing redistribution structure 115 can be provided. Routing redistribution structure 115 can be provided over component encapsulant 116, die interconnects 117, and component through-interconnects 118. Die interconnects 117 can be coupled to routing redistribution structure 115.

Routing redistribution structure 115 can comprise dielectric structure 115a and conductive structure 115b. Dielectric structure 115a can comprise one or more dielectric layers made of dielectric material (e.g., PI, BCB, PBO, resin, ABF, Si3N4, SiO2, SiON, etc.) and interleaved between layers of conductive structure 115b. The thickness of the individual layer of dielectric structure 115a can range from approximately 2 μm to approximately 50 μm. Conductive structure 115b can comprise one or more conductive layers defining signal distribution elements (e.g., traces, vias, pads, conductive paths, UBMs, etc.). Conductive structure 115b can comprise aluminum, copper, gold, silver, nickel, or palladium. The thickness of conductive structure 115b can range from approximately 1 μm to approximately 10 μm. The thickness of conductive structure 115b can refer to individual layers of conductive structure 115b. Conductive structure 115b can distribute electrical signals in a vertical direction or a lateral direction through routing redistribution structure 115. Conductive structure 115b can electrically couple component die 111 to component through-interconnects 118.

In accordance with various examples, conductive structure 115b can comprise lower side terminals 115b1, upper side terminals 115b2, and one or more conductive layers coupling respective ones of lower side terminals 115b1 to respective ones of upper side terminals 115b2. In some examples, lower side terminals 115b1 can be provided at the lower side of routing redistribution structure 115 and can be coupled to die interconnects 117 or component through-interconnects 118. Upper side terminals 115b2 can be provided at the upper side of routing redistribution structure 115. Routing interconnect 115b3 can be provided on upper side terminal 115b2. Routing interconnects 115b3 can comprise or be referred to as bumps, pads, lands, or pillars. Routing interconnects 115b3 can comprise aluminum, copper, gold, silver, nickel, palladium, or solder. The thicknesses of routing interconnects 115b3 can range from approximately 1 μm to approximately 50 μm.

In some examples, routing redistribution structure 115 can be a redistribution layer (“RDL”) substrate. RDL substrates can comprise one or more conductive layers and one or more dielectric layers that (a) can be formed layer by layer over an electronic device to which the RDL substrate is to be coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film.

To permit proper formation of desired photo-defined features, such photo-definable dielectric materials can omit structural reinforcers or can be filler-free, without strands, weaves, or other particles, that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si3N4), silicon oxide (SiO2), and/or SiON. The inorganic dielectric layer(s) can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate.

In some examples, routing redistribution structure 115 can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate omitting the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process.

FIG. 3E shows a cross-sectional view of routing component 110 at a later stage of manufacture. In the example shown in FIG. 3E, carrier 193 can be provided over routing redistribution structure 115. In some examples, temporary adhesive 194 can be provided between routing redistribution structure 115 and carrier 193. Temporary adhesive 194 can be configured to lose adhesive strength in response to heat or light. For example, temporary adhesive 194 can be a heat release tape (or film) or a light release tape (or film), where the adhesive strength is weakened or removed by heat or light, respectively. In some examples, the adhesive force of temporary adhesive 194 can be weakened or removed using chemicals or physical force.

In accordance with various examples, carrier 191 is removed, exposing the lower side of dielectric layer 192 and the lower side of component through-interconnects 118. Carrier 191 can be removed by grinding, etching, or peeling. In some examples, after removing carrier 191, a die attach film 119a can be coupled to the lower sides of dielectric layer 192 and component through-interconnects 118.

FIG. 3F shows a cross-sectional view of routing component 110 at a later stage of manufacture. In the example shown in FIG. 3F, carrier 193 is removed from over routing redistribution structure 115. In some examples, after the adhesive strength of temporary adhesive 194 is removed or reduced by providing heat, light, a chemical solution, or physical external force, routing carrier 193 can be separated from routing redistribution structure 115. In some examples, temporary adhesive 194 of carrier 193 can be separated from routing redistribution structure 115 while attached to carrier 193. Carrier 193 can be removed, so of routing interconnects 115b3 of routing redistribution structure 115 are exposed.

In accordance with various examples, the plurality of routing components 110, which can be in wafer or panel form (e.g., a reconstituted wafer or panel), can be singulated into individual routing components 110 by sawing or cutting through component encapsulant 116, routing redistribution structure 115, dielectric layer 192, and die attach film 119a. Separated individual routing components 110 can comprise component die 111, die interconnects 117, component through-interconnects 118, component encapsulant 116, routing redistribution structure 115, dielectric layer 192, and die attach film 119a. In some examples, routing components 110 can be singulated using a blade, a laser, or plasma as a singulation tool. After singulation, the lateral sides of routing redistribution structure 115 and component encapsulant 116 can be coplanar and can define, at least a portion, of the sidewalls of routing components 110.

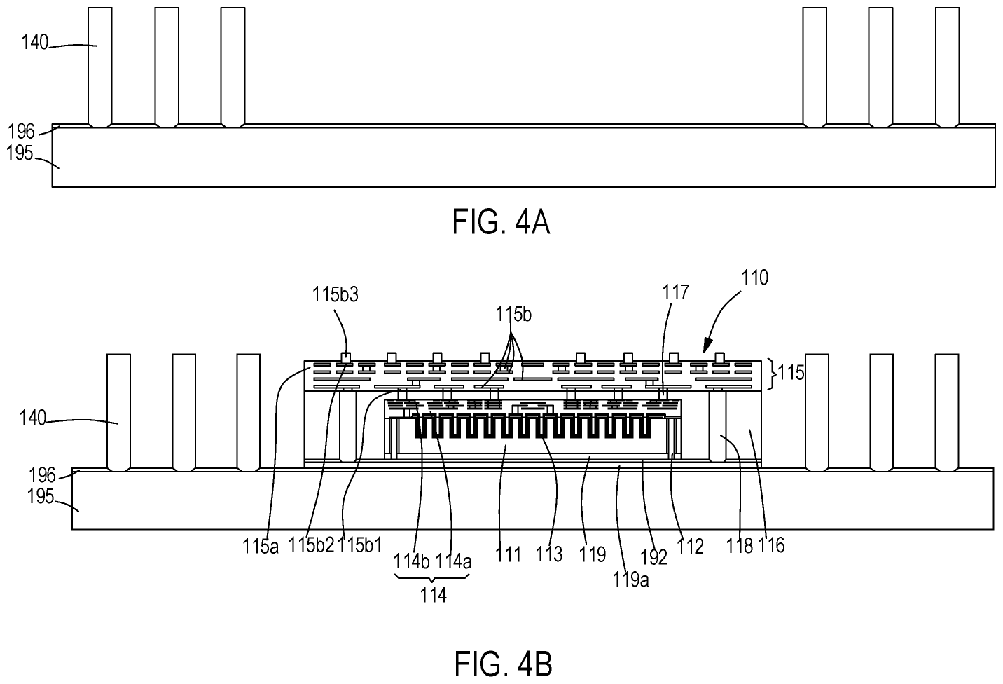

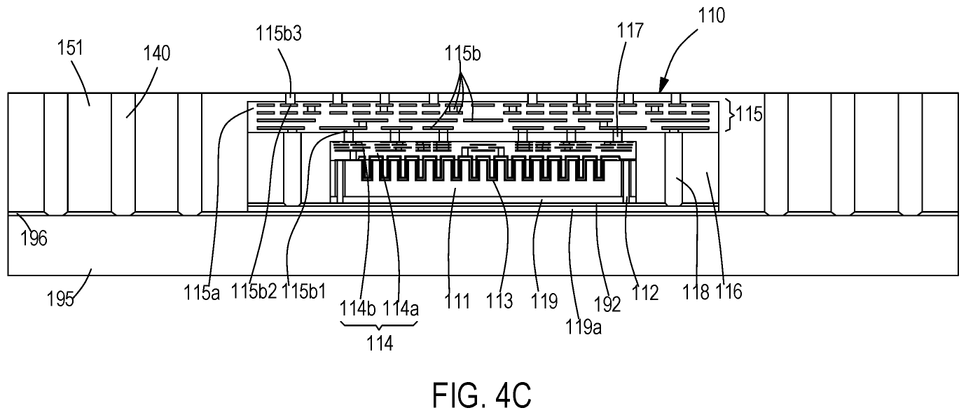

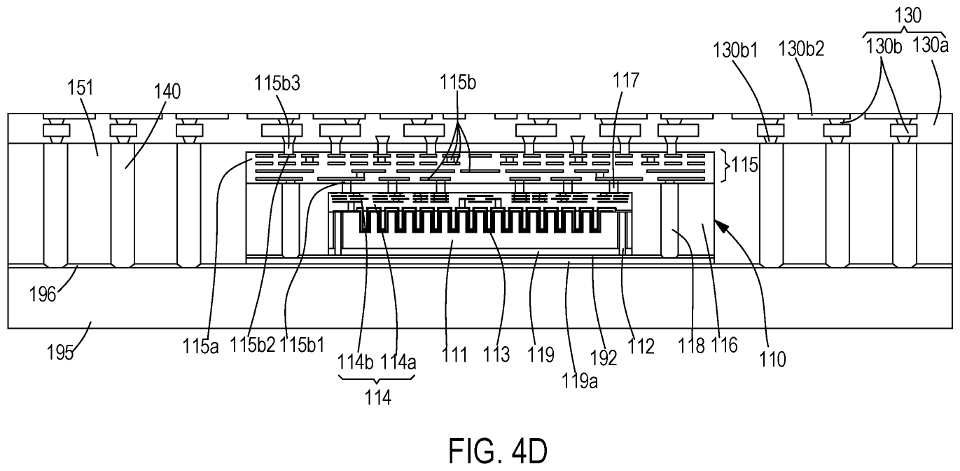

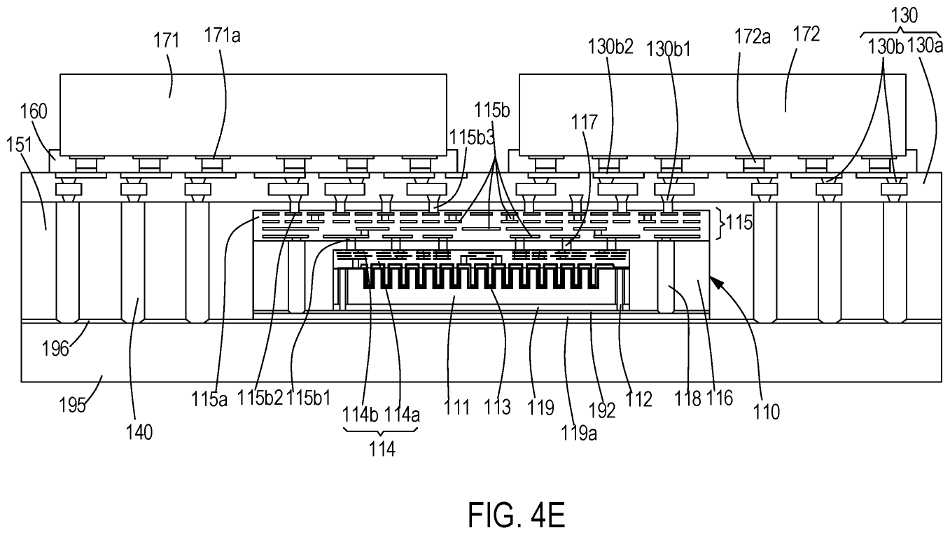

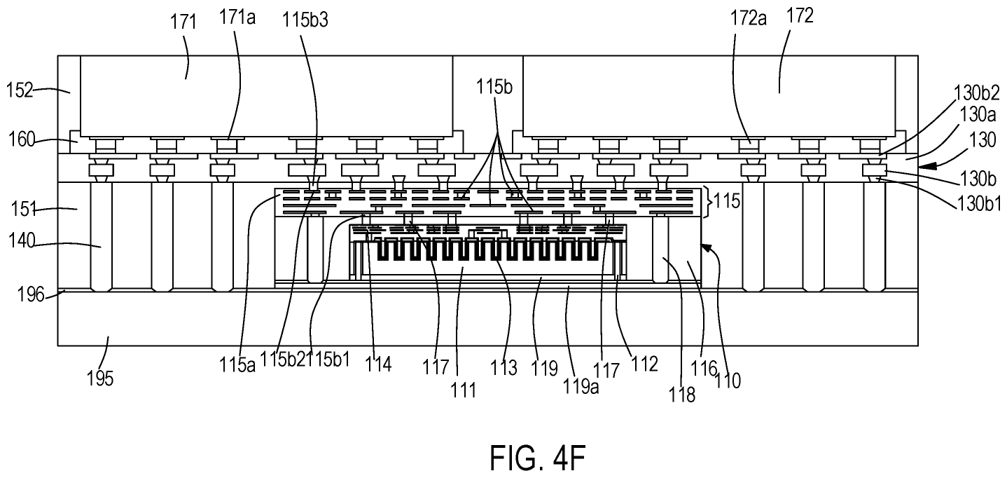

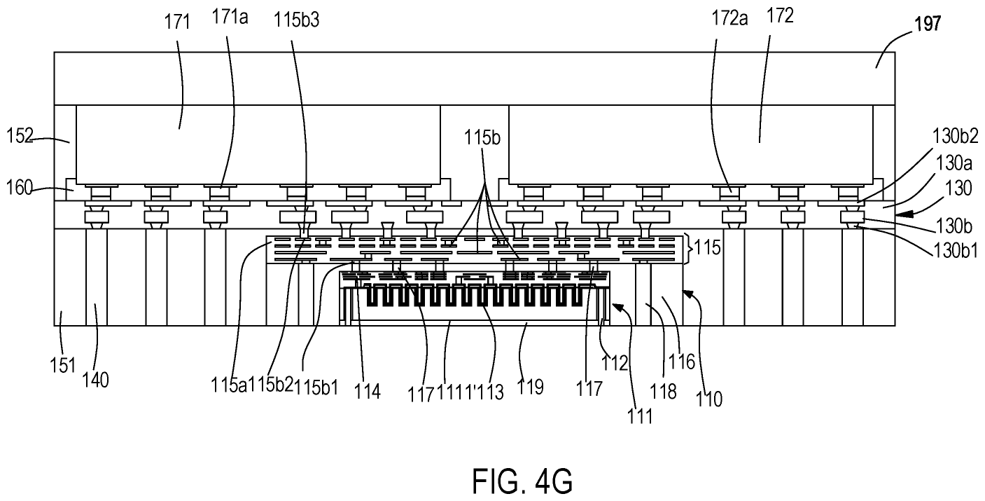

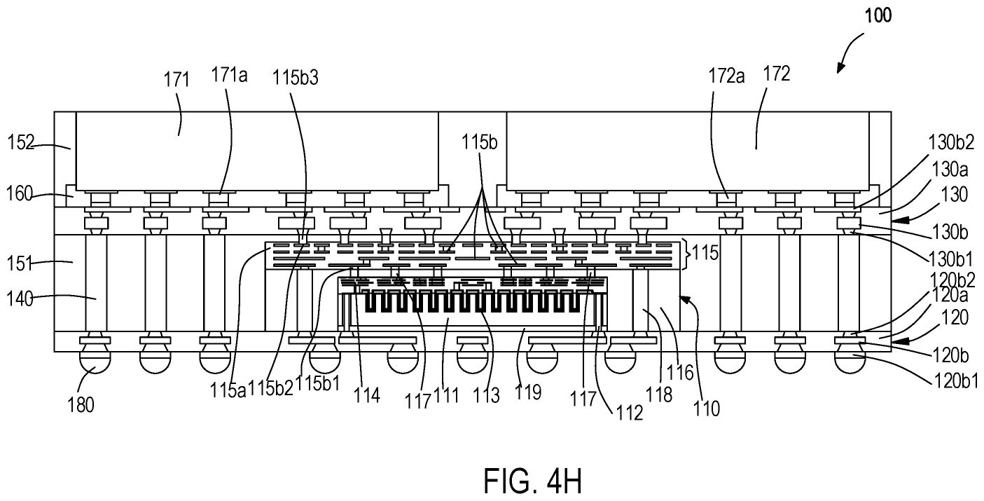

FIGS. 4A to 4H show cross-sectional views of an example method for manufacturing an example electronic device 100. While one electronic device 100 is shown in FIGS. 4A to 4H, it is contemplated and understood that a plurality of electronic devices 100 can be simultaneously (or nearly simultaneously) formed in a wafer or panel form. The wafer or panel having multiple electronic devices 100 can be sawed in a singulation step, as described below with reference to FIG. 4H, to provide individual electronic devices 100.

FIG. 4A shows a cross-sectional view of electronic device 100 at an early stage of manufacture. In the example shown in FIG. 4A, device through-interconnects 140 can be provided on carrier 195. In some examples, carrier 195 can be provided in the form of a circular wafer or a rectangular panel. In some examples, carrier 195 can comprise silicon, glass, ceramic, or metal. In some examples, dielectric layer 196 can be provided on carrier 195. Dielectric layer 196 can be patterned to provide openings in dielectric layer 196. Device through-interconnects 140 can be provided over carrier 195 and in the opening in dielectric layer 196. Each of the device through-interconnects 140 can have a lower side proximate carrier 195, an upper side opposite the lower side, and lateral sides between the lower side and the upper side. Device through-interconnects 140 can comprise or be referred to as pillars, posts, through mold vias (TMVs), copper core solder balls (CCBs), solder balls, or wires. Device through-interconnects 140 can be provided by electroless plating, electrolytic plating, sputtering, reflow, or wire bonding. In some examples, device through-interconnects 140 can comprise aluminum, copper, gold, silver, nickel, palladium, or solder. The thickness (or height) of device through-interconnects 140 can range from approximately 150 μm to approximately 400 μm. The width of device through-interconnects 140 can range from approximately 50 μm to approximately 150 μm.

FIG. 4B shows a cross-sectional view of electronic device 100 at a later stage of manufacture. In the example shown in FIG. 4B, routing component 110 can be provided on carrier 195. In some examples, die attach film 119a, on the lower side of routing component 110, can couple routing component 110 to dielectric layer 196. In some examples, routing component 110 can be located between device through-interconnects 140. The lateral sides of routing component 110 can be spaced apart from the lateral sides of device through-interconnects 140. Device through-interconnects 140 can be located adjacent one, two, three, or all four lateral sides of routing component 110. In some examples, the upper side of routing component 110 (e.g., the upper side of routing interconnects 115b3) can be coplanar with the upper sides of device through-interconnects 140.

FIG. 4C shows a cross-sectional view of electronic device 100 at a later stage of manufacture. In the example shown in FIG. 4C, lower encapsulant 151 can be provided. In some examples, lower encapsulant 151 can surround, cover, or contact routing component 110 and device through-interconnects 140. In some examples, lower encapsulant 151 can cover the lateral and upper sides of routing component 110. In some examples, lower encapsulant 151 can cover the lateral and upper sides of device through-interconnects 140. In some examples, lower encapsulant 151 can comprise or be referred to as an epoxy molding compound, resin, filler-reinforced polymer, a B-stage compression film, or gel. In some examples, lower encapsulant 151 can comprise epoxy resin or phenolic resin, carbon black, and silica filler. In some examples, lower encapsulant 151 can be provided by compression molding, transfer molding, liquid encapsulant molding, vacuum lamination, paste printing, or film assistant molding. The thickness of lower encapsulant 151 can range from approximately 150 μm to approximately 500 μm. Lower encapsulant 151 can protect routing component 110 and device through-interconnects 140 from external elements or environment exposure.

In accordance with various examples, the upper sides of device through-interconnects 140 and routing interconnects 115b3 can be exposed at the upper side of lower encapsulant 151. In some examples, lower encapsulant 151 can initially be provided covering the upper sides of device through-interconnects 140 or routing interconnects 115b3. In such an example, the thickness of lower encapsulant 151 can be reduced by grinding. After grinding, the upper side of device through-interconnects 140, the upper side of routing interconnects 115b3, and the upper side of device encapsulant 151 can be coplanar.

FIG. 4D shows a cross-sectional view of electronic device 100 at a later stage of manufacture. In the example shown in FIG. 4D, upper redistribution structure 130 can be provided over the upper side of lower encapsulant 151. Upper redistribution structure 130 can comprise dielectric structure 130a and conductive structure 130b. Dielectric structure 130a can comprise one or more dielectric layers made of dielectric material (e.g., PI, BCB, PBO, resin, ABF, Si3N4, SiO2, SiON, etc.) and interleaved between the layers of conductive structure 130b. The thickness of dielectric structure 130a can range from approximately 2 μm to approximately 50 μm. The thickness of dielectric structure 130a can refer to the individual dielectric layers of dielectric structure 130a. Conductive structure 130b can comprise one or more conductive layers defining signal distribution elements (e.g., traces, vias, pads, conductive paths, UBMs, etc.). Conductive structure 130b can comprise aluminum, copper, gold, silver, nickel, or palladium. The thickness of conductive structure 130b can range from approximately 1 μm to approximately 10 μm. The thickness of conductive structure 130b can refer to individual layers of conductive structure 130b. Conductive structure 130b can distribute electrical signals in a vertical direction or a lateral direction through upper redistribution structure 130. Conductive structure 130b can electrically couple routing component 110 to device through-interconnects 140.

Conductive structure 130b can comprise lower side terminals 130b1, upper side terminals 130b2, and one or more conductive layers coupling respective ones of lower side terminals 130b1 to respective ones of uppers side terminals 130b2. In some examples, lower side terminals 130b1 can be provided at the lower side of upper redistribution structure 130. Lower side terminals 130b1 can be coupled to routing interconnects 115b3 and device through-interconnects 140. Upper side terminals 130b2 can be provided at the upper side of upper redistribution structure 130. Similar to routing redistribution structure 115 described above, upper redistribution structure 130 can be a redistribution layer substrate or a pre-formed or laminate substrate. For example, upper redistribution structure 130 can be formed over lower encapsulant 151 or upper redistribution structure 130 can be formed separately and then disposed over lower encapsulant 151.

FIG. 4E shows a cross-sectional view of electronic device 100 at a later stage of manufacture. In the example shown in FIG. 4E, electronic components 171 and 172 can be provided over upper redistribution structure 130. Each of electronic components 171 and 172 can have an upper side, a lower side opposite to the upper side, and lateral sides connecting the upper side and the lower side. In some examples, electronic component 171 or electronic component 172 can comprise or be referred to as one or more semiconductor die, semiconductor chips, or semiconductor packages. In some examples, electronic component 171 or electronic component 172 can comprise or be referred to as active or passive devices. In some examples, electronic component 171 or electronic component 172 can comprise a central processing unit (CPU), application processor (AP), digital signal processor (DSP), network processor, power management unit, audio processor, radio frequency (RF) circuit, wireless baseband system on chip (SoC), sensor, application specific integrated circuit (ASIC), or memory. The thicknesses of electronic components 171 and 172 can range from approximately 100 μm to approximately 780 μm.

In some examples, component interconnects 171a and 172a can comprise or be referred to as bumps, pads, or pillars. Component interconnects 171a and 172a can coupled electronic components 171 and 172 to upper side terminals 130b2 of upper redistribution structure 130. Component interconnects 171a and 172a can be coupled to upper side terminals 130b2 by reflow bonding with solder, thermocompression bonding, laser assist bonding, or thermosonic bonding. In some examples, the thicknesses of component interconnects 171a and 172a can range from approximately 10 μm to approximately 70 μm. In some examples, component interconnects 171a and 172a can be coupled to upper side terminals 130b2 by hybrid bonding (e.g., by copper-to-copper or solderless bonding). Component interconnects 171a and 172a can couple electronic components 171 and 172, respectively, to upper redistribution structure 130. While electronic components 171 and 172 are shown as being flip-chip bonded, it is contemplated and understood that electronic component 171 and/or electronic component 172 can be wire bond components. For example, component interconnects 171a or 172a can comprise wire bonds extending between the upper side of electronic component 171 or 172, respectively, and upper side terminals 130b2.

In some examples, underfill 160 can be interposed between electronic components 171 and 172 and upper redistribution structure 130. In some examples, after electronic components 171 and 172 are coupled to upper redistribution structure 130, underfill 160 can be injected into gaps between electronic components 171 and 172 and upper redistribution structure 130. In some examples, underfill 160 can be pre-coated on upper redistribution structure 130 before electronic components 171 and 172 are bonded to upper redistribution structure 130. Underfill 160 can comprise or be referred to as an insulating material or a non-conductive paste and can be free of inorganic fillers. In some examples, underfill 160 can comprise or be referred to as a capillary underfill (CUF), a non-conductive paste (NCP), a non-conductive film (NCF), an anisotropic conductive film (ACF), or an anisotropic conductive paste (ACP). While a gap is shown between the underfill 160 located under electronic component 171 and the underfill 160 located under electronic component 172, in some examples, underfill 160 can extend continuously between the undersides of electronic component 171 and electronic component 172.

FIG. 4F shows a cross-sectional view of electronic device 100 at a later stage of manufacture. In the example shown in FIG. 4F, upper encapsulant 152 can be provided over electronic components 171 and 172 and upper redistribution structure 130. In some examples, upper encapsulant 152 can surround, cover, or contact electronic components 171 and 172, underfill 160, and upper redistribution structure 130. In some examples, the upper side of upper encapsulant 152 and the upper sides of electronic components 171 and 172 can be coplanar. In some examples, upper encapsulant 152 can cover the upper sides of electronic components 171 and 172. In some examples, upper encapsulant 152 can comprise or be referred to as an epoxy molding compound, resin, filler-reinforced polymer, a B stage compression film, or gel. In some examples, upper encapsulant 152 can comprise epoxy resin or phenolic resin, carbon black, and silica filler. In some examples, upper encapsulant 152 can be provided by compression molding, transfer molding, liquid encapsulant molding, vacuum lamination, paste printing, or film assistant molding. The thickness of upper encapsulant 152 can range from approximately 150 μm to approximately 900 μm. Upper encapsulant 152 can protect electronic components 171 and 172 and upper redistribution structure 130 from exposure to external elements or environments. In some examples, upper encapsulant 152 can initially be provided in a thickness greater than desired. In such an example, the thickness of upper encapsulant 152 can be reduced or planarized by a grinding (thinning or planarization) process. In some examples, after grinding, the upper sides of electronic components 171 and 172 and the upper side of upper encapsulant 152 can be coplanar. In some examples, underfill 160 can be a molded underfill (MUF) and can be considered a part of upper encapsulant 152 (i.e., upper encapsulant 152 can be disposed between or contacting the lower side of electronic components 171 and 172 and the upper side of upper redistribution structure 130).

FIG. 4G shows a cross-sectional view of electronic device 100 at a later stage of manufacture. In the example shown in FIG. 4G, carrier 197 can be provided over electronic components 171 and 172 and upper encapsulant 152. In some examples, a temporary adhesive can be provided between carrier 197 and electronic components 171 and 172 and between carrier 197 and upper encapsulant 152. The temporary adhesive can be configured to lose adhesive strength in response to heat, light, chemicals, or physical force, similar to temporary adhesive 194, as previously described.

In accordance with various examples, carrier 195 (FIG. 4F) can be removed from over the lower sides of lower encapsulant 151, device through-interconnects 140 and routing component 110. Carrier 195 can be removed by grinding, etching, stripping, or any other suitable removal process. Removal of carrier 195 can expose the lower side of dielectric layer 196 (FIG. 4F). In some examples, dielectric layer 196 can be removed and the lower sides of device through-interconnects 140, lower encapsulant 151, and routing component 110 can be exposed by grinding or etching. In some examples, the grinding or etching can expose the lower sides of component encapsulant 116 and component through-interconnects 118 of routing component 110 and the lower side of die through-interconnect 112 of component die 111. In some examples, after grinding or etching, die attach film 119 of component die 111 can be exposed. In some examples, after grinding or etching, lower side 1111′ of component die 111 can be exposed. After grinding or etching the lower side of lower encapsulant 151, the lower side of device through-interconnects 140, and the lower side of routing component 110 can be coplanar. For example, the lower side of lower encapsulant 151, the lower side of device through-interconnects 140, the lower side of component encapsulant 116, the lower side of component through-interconnects 118, the lower side of die through-interconnects 112, and the lower side of die attach film 119 or lower side 1111′ of component die 111 can be coplanar.

FIG. 4H shows a cross-sectional view of electronic device 100 at a later stage of manufacture. In the example shown in FIG. 4H, lower redistribution structure 120 can be provided. Lower redistribution structure 120 can be provided over the lower sides of lower encapsulant 151, device through-interconnects 140, and routing component 110. Lower redistribution structure 120 can comprise dielectric structure 120a and conductive structure 120b. Dielectric structure 120a can comprise one or more dielectric layers made of dielectric material (e.g., PI, BCB, PBO, resin, ABF, Si3N4, SiO2, SiON, etc.) and interleaved between layers of conductive structure 120b. The thickness of dielectric structure 120a can range from approximately 2 μm to approximately 50 μm. The thickness of dielectric structure 120a can refer to individual layers of dielectric structure 120a. Conductive structure 120b can comprise one or more conductive layers defining signal distribution elements (e.g., traces, vias, pads, conductive paths, UBMs, etc.). Conductive structure 120b can comprise aluminum, copper, gold, silver, nickel, palladium, or any other suitable electrically conductive material. The thickness of conductive structure 120b can range from approximately 1 μm to approximately 10 μm. The thickness of conductive structure 120b can refer to individual layers of conductive structure 120b. Conductive structure 120b can comprise lower side terminals 120b1 and upper side terminals 120b2. In some examples, lower side terminals 120b1 can be provided at the lower side of lower redistribution structure 120 and upper side terminals 120b2 can be provided at the upper side of lower redistribution structure 120. Similar to routing redistribution structure 115 described above, lower redistribution structure 120 can be a redistribution layer substrate or a pre-formed or laminate substrate. For example, lower redistribution structure 120 can be formed over lower encapsulant 151 and routing component 110 or lower redistribution structure 120 can be formed separately and then disposed over lower encapsulant 151 and routing component 110.

Conductive structure 120b can distribute electrical signals in a vertical direction or a lateral direction through lower redistribution structure 120. Conductive structure 120b can be coupled to die through-interconnects 112, component through-interconnects 118, and device through-interconnects 140. For example, upper side terminals 120b2 can be coupled to die through-interconnects 112, component through-interconnects 118, or device through-interconnects 140. Device through-interconnects 140 can couple conductive structure 130b of upper redistribution structure 130 to conductive structure 120b of lower redistribution structure 120. Component through-interconnects 118 can couple conductive structure 115b of routing redistribution structure 115 to conductive structure 120b of lower redistribution structure 120.

In accordance with various examples, external interconnects 180 can be provided on lower side terminals 120b1. In some examples, external interconnects 180 can be coupled to the lower side of lower side terminals 120b1. In some examples, external interconnects 180 can comprise or be referred to as solder bumps, bumps, pads, or pillars. In some examples, external interconnects 180 can comprise tin, silver, lead, copper, Sn—Pb, Sn37—Pb, Sn95—Pb, Sn—Pb—Ag, Sn—Cu, Sn—Ag, Sn—Au, Sn—Bi, or Sn—Ag—Cu. In some examples, the thicknesses (or diameters) of external interconnects 180 can range from approximately 70 μm to approximately 80 μm. External interconnects 180 can couple electronic device 100 to an external device.

In some examples, as described above, a plurality of electronic devices 100 can be provided in wafer or panel form (e.g., a reconstituted wafer or panel), and individual electronic devices 100 can be provided by sawing or cutting through upper encapsulant 152, upper redistribution structure 130, lower encapsulant 151, and lower redistribution structure 120. Separated individual electronic devices 100 can comprise electronic components 171 and 172, routing component 110, upper encapsulant 152, upper redistribution structure 130, lower encapsulant 151, lower redistribution structure 120, device through-connects 140, and external interconnects 180. In some examples, electronic devices 100 can be singulated using a blade, a laser, or plasma as a singulation tool. After singulation, the lateral sides of upper encapsulant 152, the lateral sides of upper redistribution structure 130, the lateral sides of lower encapsulant 151, and the lateral sides of lower redistribution structure 120 can be coplanar.

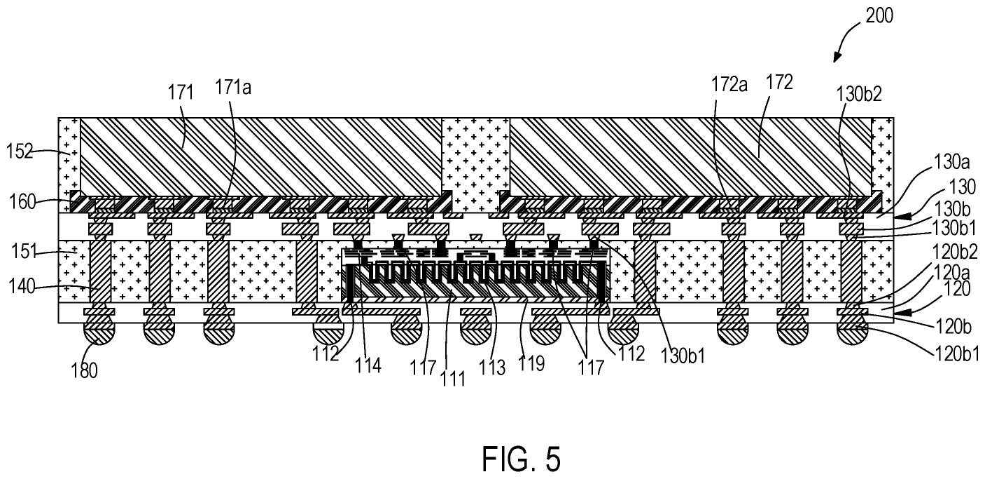

FIG. 5 shows a cross-sectional view of an example electronic device 200. In accordance with various examples, electronic device 200 can be similar to electronic device 100 of FIG. 1. For example, electronic device 200 can be similar to electronic device 100 in terms of electronic components 171 and 172, upper encapsulant 152, underfill 160, upper redistribution structure 130, lower encapsulant 151, lower redistribution structure 120, device through-connects 140, external interconnects 180, and component die 111. In some examples, lower encapsulant 151 of electronic device 200 can cover, surround, or contact component die 111, die interface structure 114, or die interconnects 117. For example, lower encapsulant 151 can be disposed over or contact the lateral sides of component die 111. Lower encapsulant 151 can be disposed over or contact the lateral sides and the upper side of die interface structure 114. Lower encapsulant 151 can be disposed over or contact the lateral sides of die interconnects 117. In electronic device 200, die interconnects 117 can be coupled to die interface structure 114 and conductive structure 130b of upper redistribution structure 130. For example, die interconnects 117 can be on or contacting lower side terminals 130b1 of conductive structure 130b. In this way, the component die 111 can be electrically coupled to upper redistribution structure 130 through die interface structure 114 even though routing redistribution structure 115 (FIG. 1) is omitted. Moreover, via the its connection to the upper redistribution structure 130, the die interface structure 114 in some embodiments may route signals between electronic components 171 and 172.

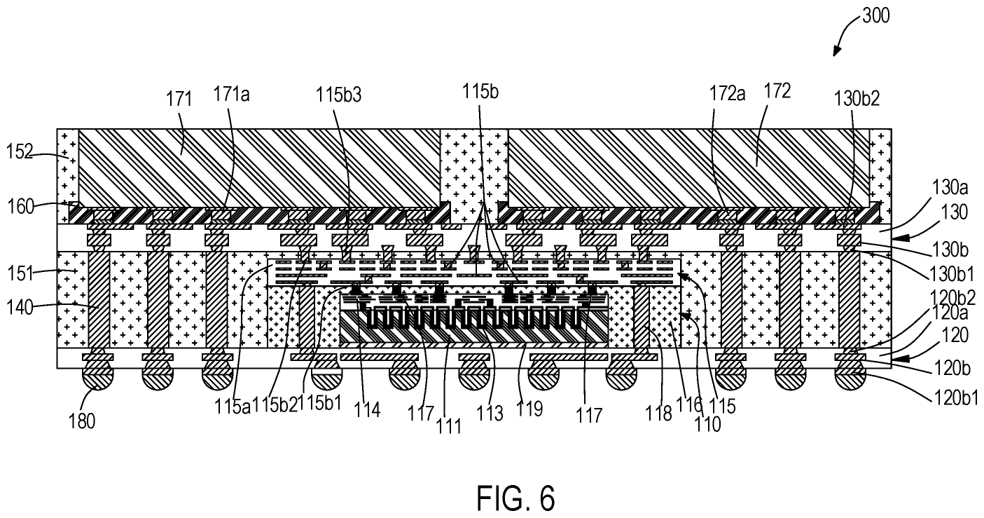

FIG. 6 shows a cross-sectional view of an example electronic device 300. In accordance with various examples, electronic device 300 can be similar to electronic device 100 of FIG. 1. For example, electronic device 300 can be similar to electronic device 100 in terms of electronic components 171 and 172, upper encapsulant 152, underfill 160, upper redistribution structure 130, lower encapsulant 151, lower redistribution structure 120, device through-connects 140, external interconnects 180, routing structure 115, component encapsulant 116, and component through-interconnects 118. In the example of FIG. 6, die through-interconnects 112 (FIG. 1) can be omitted from component die 111. For example, lower side 1111′ of component die 111 can be devoid of electrical interconnections to conductive structure 120b of lower redistribution structure 120. In some examples, component die 111 can be electrically connected to conductive structure 120b and external interconnect 180 through component through-interconnects 118, routing redistribution structure 115, die interconnects 117, and die interface structure 114. In this way, passive element 113 of component die 111 can be electrically coupled to upper redistribution structure 130 even though die through-interconnects 112 are omitted.

Thus, in various embodiments, an electronic device can include a lower redistribution structure, an upper redistribution structure, a first electronic component coupled to the upper redistribution structure, a second electronic component coupled to the upper redistribution structure, and a routing component. The routing component can include a routing redistribution structure, a component die, component through-interconnects, and a component encapsulant. The routing redistribution structure can be on the component encapsulant and coupled to the upper redistribution structure. The component die can include a component die substrate and die interface structure on the component die substrate. The die interface structure can be coupled to the routing redistribution structure. The component through-interconnects can extend through the component encapsulant and couple the routing redistribution structure to the lower redistribution structure.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device comprising:
a lower redistribution structure comprising a lower redistribution structure upper side and a lower redistribution structure lower side;
an upper redistribution structure comprising an upper redistribution structure upper side and an upper redistribution structure lower side;
a first electronic component coupled to the upper redistribution structure upper side;
a second electronic component coupled to the upper redistribution structure upper side; and
a routing component comprising a routing redistribution structure, a component die, component through-interconnects, and a component encapsulant;
wherein the component encapsulant comprises a component encapsulant upper side and a component encapsulant lower side;
wherein the routing redistribution structure comprises a routing redistribution structure upper side coupled to the upper redistribution structure lower side and a routing redistribution structure lower side on the component encapsulant upper side;
wherein the component die comprises a component die substrate and a die interface structure on the component die substrate;
wherein the die interface structure is coupled to the routing redistribution structure lower side; and
wherein the component through-interconnects extend through the component encapsulant and couple the routing redistribution structure lower side to the lower redistribution structure upper side.

2. The electronic device of claim 1, comprising routing interconnects that couple the routing redistribution structure to the upper redistribution structure.

3. The electronic device of claim 1, comprising die interconnects that couple the die interface structure to the routing redistribution structure.

4. The electronic device of claim 1, wherein an upper surface of the component die substrate comprises one or more passive elements.

5. The electronic device of claim 4, comprising die through-interconnects that extend through the component die substrate and couple the lower redistribution structure to the one or more passive elements.

6. The electronic device of claim 4, wherein the one or more passive elements comprise one or more deep trench capacitors.

7. The electronic device of claim 4, wherein the one or more passive elements are coupled to the die interface structure.

8. The electronic device of claim 1, comprising an upper encapsulant that laterally surrounds the first electronic component and the second electronic component.

9. The electronic device of claim 8, comprising underfill between a lower side of the first electronic component and the upper redistribution structure upper side.

10. The electronic device of claim 1, comprising a lower encapsulant that laterally surrounds the routing component.

11. The electronic device of claim 10, comprising device through-interconnects that pass through the lower encapsulant and couple the upper redistribution structure to the lower redistribution structure.

12. An electronic device comprising:
a lower redistribution structure comprising a lower redistribution structure upper side and a lower redistribution structure lower side;
an upper redistribution structure comprising an upper redistribution structure upper side and an upper redistribution structure lower side;
a first electronic component coupled to the upper redistribution structure upper side;
a second electronic component coupled to the upper redistribution structure upper side; and
a component die comprising a component die lower side coupled to the lower redistribution structure upper side and component die upper side coupled to the upper redistribution structure lower side;
wherein the component die comprises a component die substrate, one or more passive elements along an upper surface of the component die substrate, a die interface structure over the component die substrate and the one or more passive elements, and die through-interconnects that pass through the component die substrate and couple the one or more passive elements to the lower redistribution structure.

13. The electronic device of claim 12, comprising die interconnects that couple the die interface structure to the upper redistribution structure.

14. The electronic device of claim 12, wherein the one or more passive elements comprise one or more deep trench capacitors.

15. The electronic device of claim 12, wherein the one or more passive elements are coupled to the upper redistribution structure.

16. The electronic device of claim 1, comprising an upper encapsulant that laterally surrounds the first electronic component and the second electronic component.

17. The electronic device of claim 16, comprising underfill between a lower side of the first electronic component and the upper redistribution structure upper side.

18. The electronic device of claim 12, comprising a lower encapsulant that laterally surrounds the component die.

19. The electronic device of claim 18, comprising device through-interconnects that pass through the lower encapsulant and couple the upper redistribution structure to the lower redistribution structure.

20. A method of manufacturing an electronic device, the method comprising:
providing a lower redistribution structure comprising a lower redistribution structure upper side and a lower redistribution structure lower side;
providing an upper redistribution structure comprising an upper redistribution structure upper side and an upper redistribution structure lower side;
providing a routing component on the lower redistribution structure upper side, wherein:
the routing component comprises a routing redistribution structure, a component die, component through-interconnects, and a component encapsulant,
the component encapsulant comprises a component encapsulant upper side and a component encapsulant lower side;
the routing redistribution structure comprises a routing redistribution structure upper side coupled to the upper redistribution structure lower side and a routing redistribution structure lower side on the component encapsulant upper side;
the component die comprises a component die substrate and a die interface structure on the component die substrate;
the die interface structure is coupled to the routing redistribution structure lower side; and
the component through-interconnects extend through the component encapsulant and coupled the routing redistribution structure lower side to the lower redistribution structure upper side;
providing a first electronic component coupled to the upper redistribution structure upper side; and
providing a second electronic component coupled to the upper redistribution structure upper side.
